(19) United States
(12) Patent Application Publication
(10) Pub. No.: US 2023/0112873 A1
(43) Pub. Date: Apr. 13, 2023

(54) INTEGRATED PRECLEAN-DEPOSITION SYSTEM FOR OPTICAL FILMS

(71) Applicant: Applied Materials, Inc., Santa Clara, CA (US)

(72) Inventors: Kenichi OHNO, Sunnyvale, CA (US); Visweswaren SIVARAMAKRISHNAN, Cupertino, CA (US); Ludovic GODET, Sunnyvale, CA (US)

(21) Appl. No.: 17/937,415

(22) Filed: Sep. 30, 2022

Related U.S. Application Data
(60) Provisional application No. 63/253,695, filed on Oct. 8, 2021.

(51) Int. Cl. C23C 14/56; C23C 14/24

(52) U.S. Cl. CPC C23C 14/564; C23C 14/24; H01J 37/32357

(57) ABSTRACT

Embodiments of the present disclosure generally relate to optical devices. More specifically, embodiments described herein relate to a system and method of forming an optical device film. In an embodiment, a method is provided for positioning a substrate in a pre-cleaning chamber disposed in a cluster processing system and pre-cleaning the substrate to remove a native oxide layer from one or more surfaces of the substrate. The substrate is then transferred in an air free state to a deposition chamber disposed in the cluster processing system for forming an optical device film layer on the substrate.

### RELATED APPLICATIONS

This application claims benefit of and priority to U.S. Provisional Patent Application No. 63/253,695, filed Oct. 8, 2021, which is herein incorporated in its entirety by reference for all purposes.

### BACKGROUND

### Field

Embodiments of the present disclosure generally relate to optical devices. More specifically, embodiments described herein relate to a deposition system and a method forming an optical device film with the deposition system.

### Description of the Related Art

Virtual reality is generally considered to be a computer generated simulated environment in which a user has an apparent physical presence. A virtual reality experience can be generated in 3D and viewed with a head-mounted display (HMD), such as glasses or other wearable display devices that have near-eye display panels as lenses to display a virtual reality environment that replaces an actual environment.

Augmented reality, however, enables an experience in which a user can still see through the display lenses of the glasses or other HMD device to view the surrounding environment, yet also see images of virtual objects that are generated to appear as part of the environment. Augmented reality can include any type of input, such as audio and haptic inputs, as well as virtual images, graphics, and video that enhances or augments the environment that the user experiences. As an emerging technology, there are many challenges and design constraints with augmented reality.

One such challenge is displaying a virtual image overlaid on an ambient environment. Optical devices including waveguide combiners, such as augmented reality waveguide combiners, and flat optical devices, such as metasurfaces, are used to assist in overlaying images. Generated light is propagated through an optical device until the light exits the optical device and is overlaid on the ambient environment.

Accordingly, what is needed in the art is a deposition system and a method of forming an optical device film with the deposition system.

### SUMMARY

In one embodiment, a method for forming an optical device film layer on a substrate is provided. The method includes pre-cleaning a substrate in a pre-cleaning chamber disposed in a cluster processing system to remove a native oxide layer from a top surface of the substrate. When the native oxide layer is removed from the substrate, the substrate is transferred to a deposition chamber disposed in the cluster processing system. The substrate is transferred to the deposition chamber while being maintained in an air free state to prevent regrowth of the native oxide layer. Then, an optical device film layer is formed on the top surface of the substrate in the deposition chamber disposed in the cluster processing system.

In another embodiment, a method for forming an optical device film layer on a silicon carbide (SiC) substrate is provided. The method includes positioning a SiC substrate in a pre-cleaning chamber of a cluster processing system and pre-cleaning the SiC substrate in the pre-cleaning chamber disposed in a cluster processing system to remove a native SiOC layer from one or more surfaces of the SiC substrate.

When the native SiOC layer is removed from the SiC substrate, the Sic substrate is transferred to a deposition chamber disposed in the cluster processing system. The SiC substrate is transferred to the deposition chamber while being maintained in an air free state to prevent growth of SiOC on the one or more surfaces of the SiC substrate. Then, an optical device film layer on the one or more surfaces of the SiC substrate in the deposition chamber disposed in the cluster processing system.

In yet another embodiment, cluster processing system for forming an optical device film layer on a substrate is provided. The system includes a pre-cleaning chamber configured to remove a native oxide layer, a deposition chamber configured to form an optical device film layer, and a transfer chamber configured to maintain an air free environment when transitioning between the pre-cleaning chamber and the first deposition chamber. The system may also include a computer readable media that when executed by a controller of the cluster processing system, causes the cluster processing system to pre-clean a substrate in a pre-cleaning chamber disposed in the cluster processing system to remove the native oxide layer from one or more surfaces of the substrate, transfer the substrate to a deposition chamber disposed in the cluster processing system while maintaining the substrate in an air free state, and form an optical device film layer on the substrate in the deposition chamber disposed in the cluster processing system.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic view of a pre-clean processing chamber which may be utilized to perform a pre-clean process on a substrate, according to certain embodiments described herein.

FIG. 2 is a schematic view of an apparatus that may be utilized to perform a physical vapor deposition (PVD) processing process, according to certain embodiments described herein.

FIG. 3 is a schematic view of a cluster processing system that may have the processing chambers from FIGS. 1-2 incorporated thereto for practice of the example method in FIG. 4, according to certain embodiments described herein.

FIG. 4 is a flow diagram of an example method for forming an optical device film, according to certain embodiments described herein.

FIG. 5A is a schematic, cross-sectional view of an optical device substrate having a surface with an oxidized layer, according to certain embodiments described herein.

FIG. 5B is a schematic, cross-sectional view of an optical device substrate after a method of forming an optical device film, according to certain embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to optical devices. More specifically, embodiments described herein relate to a deposition system and a method of forming an optical device film with the deposition system. A deposition system as shown and described herein is provided. A method as shown and described herein is also provided.

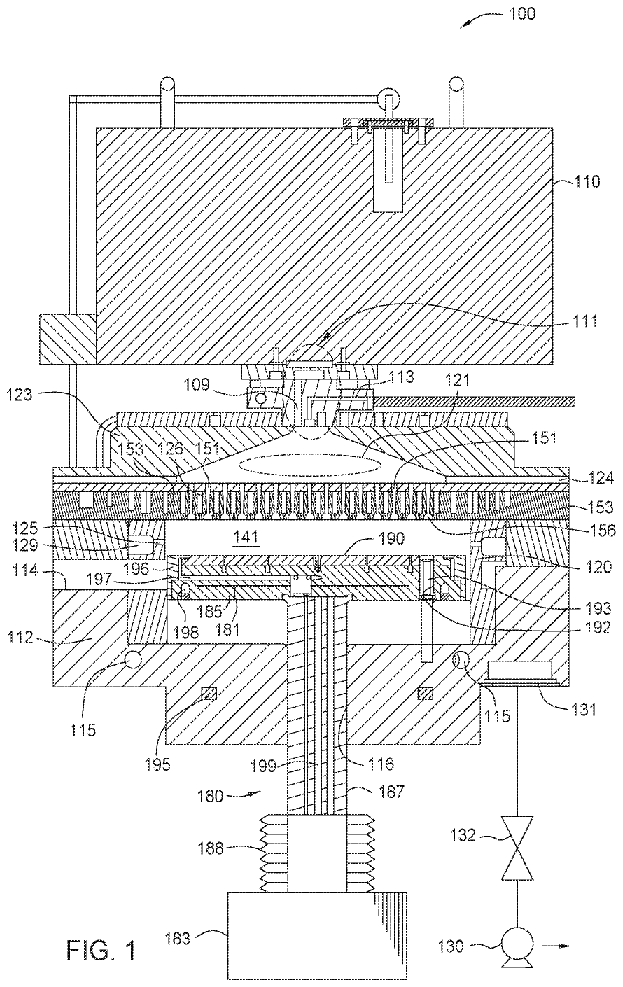

FIG. 1 is a cross sectional view of an illustrative processing chamber 100 suitable for performing a substrate pre-cleaning process as further described below. The processing chamber 100 may be configured to remove native oxide, or surface contamination from a substrate surface. The processing chamber 100 is particularly useful for performing the remote plasma surface cleaning process. The processing chamber 100 may be a Frontier™, PCxT Reactive Preclean™ (RPC), AKTIV Pre-Clean™, Siconi™ or Capa™ chamber, which is available from Applied Materials, Santa Clara, Calif. It is noted that other vacuum processing chambers available from other manufactures may also be adapted to practice the present disclosure.

The processing chamber 100 includes a chamber body 112, a lid assembly 123, and a support assembly 180. The lid assembly 123 is disposed at an upper end of the chamber body 112, and the support assembly 180 is at least partially disposed within the chamber body 112.

The chamber body 112 includes a slit valve opening 114 formed in a sidewall thereof to provide access to the interior of the processing chamber 100. The slit valve opening 114 is selectively opened and closed to allow access to the interior of the chamber body 112 by a wafer handling robot (not shown).

In one or more implementations, the chamber body 112 includes a channel 115 formed therein for flowing a heat transfer fluid therethrough. The chamber body 112 can further include a liner 120 that surrounds the support assembly 180. The liner 120 is removable for servicing and cleaning. In one or more embodiments, the liner 120 includes one or more apertures 125 and a pumping channel 129 formed therein that is in fluid communication with a vacuum system. The apertures 125 provide a flow path for gases into the pumping channel 129, which provides an egress for the gases within the processing chamber 100.

The vacuum system can include a vacuum pump 130 and a throttle valve 132 to regulate flow of gases through the processing chamber 100. The vacuum pump 130 is coupled to a vacuum port 131 disposed in the chamber body 112 and therefore, in fluid communication with the pumping channel 129 formed within the liner 120.

A remote plasma system 110 may process a halogen containing precursor, for example fluorine-containing precursor, which then travels through a gas inlet assembly 111. Two distinct gas supply channels (a first channel 109 and a second channel 113) are visible within the gas inlet assembly 111. The first channel 109 carries a gas that passes through the remote plasma system 110 (RPS), while the second channel 113 bypasses the remote plasma system 110. Either channel 109, 113 may be used for the halogen-containing precursor. On the other hand, the first channel 109 may be used for the process gas and the second channel 113 may be used for a treatment gas. A lid assembly (or conductive top portion) 123 and a perforated partition 153 (or called a showerhead) are shown with an insulating ring 124 in between, which allows an AC potential to be applied to the lid assembly 123 relative to the perforated partition 153. The AC potential strikes a plasma in a chamber plasma region 121. The process gas may travel through the first channel 109 into the chamber plasma region 121 and may be excited by a plasma in the chamber plasma region 121 alone or in combination with the remote plasma system 110. If the process gas flows through the second channel 113, then only the chamber plasma region 121 is used for excitation. The combination of the chamber plasma region 121 and/or the remote plasma system 110 may be referred to as a remote plasma system herein. The perforated partition (also referred to as a showerhead) 153 separates the chamber plasma region 121 from a substrate processing region 141 beneath the perforated partition 153. The perforated partition 153 allows a plasma present in the chamber plasma region 121 to avoid directly exciting gases in the substrate processing region 141, while still allowing excited species to travel from the chamber plasma region 121 into the substrate processing region 141.

The perforated partition 153 is positioned between the chamber plasma region 121 and the substrate processing region 141 and allows plasma effluents (excited derivatives of precursors or other gases) created within remote plasma system 110 and/or the chamber plasma region 121 to pass through a plurality of through-holes 156. The perforated partition 153 also has one or more hollow volumes 151 which can be filled with a precursor in the form of a vapor or gas and pass through the through-holes 156 into the substrate processing region 141 but not directly into the chamber plasma region 121. In order to maintain a significant concentration of excited species penetrating from the chamber plasma region 121 to the substrate processing region 141, the length 126 of the through-holes 156 may be restricted and configured in different configurations as needed.

The perforated partition 153 may be configured to serve the purpose of an ion suppressor as shown in FIG. 1. Alternatively, a separate processing chamber element may be included (not shown) which suppresses the ion concentration traveling into the substrate processing region 141. The lid assembly 123 and the perforated partition 153 may function as a first electrode and second electrode, respectively, so that the lid assembly 123 and the perforated partition 153 may receive different electric voltages. In these configurations, electrical power (e.g., RF power) may be applied to the lid 123, the perforated partition 153, or both. For example, the electrical power may be applied to the lid assembly 123 while the perforated partition 153 (serving as ion suppressor) is grounded. The substrate processing chamber 100 may include a RF generator that provides the electrical power to the lid assembly 123 and/or the perforated partition 153 as needed. The voltage applied to the lid assembly 123 may facilitate a uniform distribution of plasma (i.e., reduce localized plasma) within the chamber plasma region 121. To enable the formation of a plasma in the chamber plasma region 121, the insulating ring 124 may electrically insulate the lid assembly 123 from the perforated partition 153. The insulating ring 124 may be made from a ceramic and may have a high breakdown voltage to avoid sparking. Portions of substrate processing chamber 100 near the capacitively-coupled plasma components just described may further include a cooling unit (not shown) that includes one or more cooling fluid channels to cool surfaces exposed to the plasma with a circulating coolant (e.g., water).

In the embodiment shown, the perforated partition 153 may distribute (via through-holes 156) process gases which contain hydrogen, fluorine and/or plasma effluents of such process gases upon excitation by a plasma in the chamber plasma region 121. In embodiments, the process gas introduced into the remote plasma system 110 and/or the chamber plasma region 121 may contain fluorine (such as F2 or HF). The process gas may also include a carrier gas such as helium, argon, hydrogen (H2), etc. Plasma effluents may include ionized or neutral derivatives of the process gas and may also be referred to herein as radical-fluorine referring to the atomic constituent of the process gas introduced.

The through-holes 156 are configured to suppress the migration of ionically-charged species out of the chamber plasma region 121 while allowing uncharged neutral or radical species to pass through the perforated partition 153 into the substrate processing region 141. These uncharged species may include highly reactive species that are transported with less-reactive carrier gas by the through-holes 156. As noted above, the migration of ionic species by the through-holes 156 may be reduced, and in some instances completely suppressed. Controlling the amount of ionic species passing through the perforated partition 153 provides increased control over the gas mixture brought into contact with the underlying wafer substrate, which in turn increases control of the deposition and/or etch characteristics of the gas mixture. For example, adjustments in the ion concentration of the gas mixture can significantly alter its etch selectivity (e.g., silicon nitride/oxide: silicon etch ratios).

In embodiments, the number of the through-holes 156 may be between about 60 and about 2000. The through-holes 156 may have a variety of shapes but are most easily made round. There is also latitude in choosing the cross-sectional shape of through-holes, which may be made conical, cylindrical or combinations of the two shapes. The through-holes 156 may be configured to control the passage of the plasma-activated gas (i.e., the ionic, radical, and/or neutral species) through the perforated partition 153. For example, the aspect ratio of the holes (i.e., the whole diameter to length) and/or the geometry of the holes may be controlled so that the flow of ionically-charged species in the activated gas passing through the perforated partition 153 is reduced. The through-holes 156 in the perforated partition 153 may include a tapered portion that faces the chamber plasma region 121, and a cylindrical portion that faces the substrate processing region 141. The cylindrical portion may be proportioned and dimensioned to control the flow of ionic species passing into the substrate processing region 141. An adjustable electrical bias may also be applied to the perforated partition 153 as an additional means to control the flow of ionic species through the perforated partition 153.

Alternatively, the through-holes 156 may have a smaller inner diameter (ID) toward the top surface of the perforated partition 153 and a larger ID toward the bottom surface. In addition, the bottom edge of the through-holes 156 may be chamfered to help evenly distribute the plasma effluents in the substrate processing region 141 as the plasma effluents exit the showerhead and promote even distribution of the plasma effluents and precursor gases. The smaller ID may be placed at a variety of locations along the through-holes 156 and still allow the perforated partition 153 to reduce the ion density within the substrate processing region 141. The reduction in ion density results from an increase in the number of collisions with walls prior to entry into the substrate processing region 141. Each collision increases the probability that an ion is neutralized by the acquisition or loss of an electron from the wall. Generally speaking, the smaller ID of the through-holes 156 may be between about 0.2 mm and about 20 mm. In other embodiments, the smaller ID may be between about 1 mm and 6 mm or between about 0.2 mm and about 5 mm. Further, aspect ratios of the through-holes 156 (i.e., the smaller ID to hole length) may be approximately 1 to 20. The smaller ID of the through-holes 156 may be the minimum ID found along the length of the through-holes. The cross sectional shape of through-holes 156 may be generally cylindrical, conical, or any combination thereof.

The support assembly 180 can include a support member 185 to support a substrate (not shown in FIG. 1) for processing within the chamber body 112. The support member 185 can be coupled to a lift mechanism 183 through a shaft 187 which extends through a centrally-located opening 116 formed in a bottom surface of the chamber body 112. The lift mechanism 183 can be flexibly sealed to the chamber body 112 by a bellows 188 that prevents vacuum leakage from around the shaft 187.

The support member 185 can include bores 192 formed therethrough to accommodate lift pins 193, one of which is shown in FIG. 1. Each lift pin 193 is constructed of ceramic or ceramic-containing materials, and are used for substrate-handling and transport. The lift pin 193 is moveable within its respective bore 192 when engaging an annular lift ring 195 disposed within the chamber body 112. The support assembly 180 can further include an edge ring 196 disposed about the support member 185.

The temperature of the support assembly 180 can be controlled by a fluid circulated through a fluid channel 198 embedded in the body of the support member 185. In one or more implementations, the fluid channel 198 is in fluid communication with a heat transfer conduit 199 disposed through the shaft 187 of the support assembly 180. The fluid channel 198 is positioned about the support member 185 to provide a uniform heat transfer to the substrate receiving surface of the support member 185. The fluid channel 198 and heat transfer conduit 199 can flow heat transfer fluids to either heat or cool the support member 185. Any suitable heat transfer fluid may be used, such as water, nitrogen, ethylene glycol, or mixtures thereof. The support assembly 180 can further include an embedded thermocouple (not shown) for monitoring the temperature of the support surface of the support member 185. For example, a signal from the thermocouple may be used in a feedback loop to control the temperature or flow rate of the fluid circulated through the fluid channel 198.

The support member 185 can be moved vertically within the chamber body 112 so that a distance between support member 185 and the lid assembly 140 can be controlled. A sensor (not shown) can provide information concerning the position of support member 185 within processing chamber 100.

A system controller (not shown) can be used to regulate the operations of the processing chamber 100. The system controller can operate under the control of a computer program stored on a memory of a computer. The computer program may include instructions that enable the preclean process described below to be performed in the processing chamber 100. For example, the computer program can dictate the process sequencing and timing, mixture of gases, chamber pressures, RF power levels, susceptor positioning, slit valve opening and closing, wafer cooling and other parameters of a particular process.

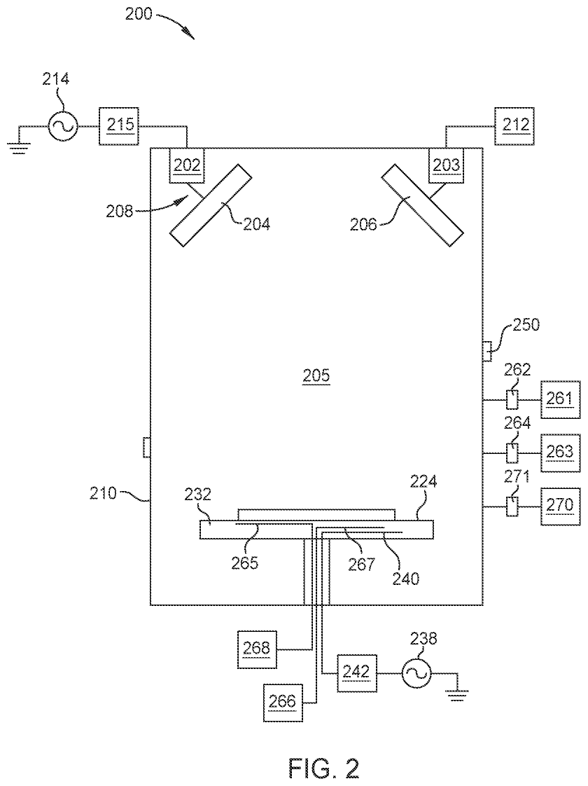

FIG. 2 is a schematic cross-sectional view of a processing chamber 200 according to one embodiment described herein. The processing chamber 200 may be a deposition chamber, such as a PVD chamber 200. The processing chamber 200 may be used to perform the methods described herein and configured at least to deposit a thin film on a substrate surface. It is to be understood that the chamber 200 is an exemplary physical vapor deposition (PVD) chamber and other PVD chambers, including PVD chambers from other manufacturers, may be used with or modified to accomplish the methods of the present disclosure. While PVD is discussed in this disclosure, various deposition techniques, such as chemical vapor deposition (CVD), plasma enhanced chemical vapor deposition (PECVD), atomic layer deposition (ALD), plasma enhanced atomic layer deposition (PEALD), low pressure chemical vapor deposition (LPCVD), etc., are also contemplated.

The processing chamber 200 includes one or more cathodes 202, 203 that have a corresponding single target or a plurality of targets, attached to the chamber body 210 (e.g., via a chamber body adapter). In the implementation shown in FIG. 2, the processing chamber 200 includes at least one first target 204 and at least one second target 206. The first target 204 includes at least one first material described herein and the second target 206 includes at least one second material described herein. Each cathode (e.g., the first target 204 and second target 206) may be coupled to a DC power source 212 and/or an RF power source 214 and matching network 216.

The processing chamber 200 is configured to include a substrate support 232 having a support surface 234 to support the substrate. The processing chamber 200 includes an opening 250 (e.g., a slit valve) through which an end effector (not shown) extends to place a substrate onto lift pins (not shown) for lowering the substrate onto the support surface 234.

The processing chamber 200 includes a sputter gas source 261 operable to supply a sputter gas to a process volume 205. A plasma 198 can be generated in the processing volume 205 from a non-reactive sputter gas (such as argon (Ar), krypton (Kr), etc., and/or from a process gas including an oxygen-containing gas (e.g., O₂) for oxide deposition or a nitrogen-containing gas (e.g., N₂) for nitride deposition, according to some embodiments. The present disclosure contemplates that other sputter gas(es) may also be used.

A gas flow controller 262 is disposed between the sputter gas source 261 and the process volume 205 to control a flow of the sputter gas from the sputter gas source 261 to the process volume 205. The processing chamber 200 also includes a reactive gas source 263 operable to supply a reactive gas, such as an oxygen-containing gas or nitrogen-containing gas to the process volume 205. A gas flow controller 264 is disposed between the reactive gas source 263 and the process volume 205 to control a flow of the reactive gas from the reactive gas source 263 to the process volume 205. The processing chamber 200 may include a precursor gas source 270 operable to supply a precursor gas to the process volume 205. In one embodiment, which can be combined with other embodiments, a gas flow controller 271 is disposed between the precursor gas source 270 and the process volume 205 to control a flow of the precursor gas from the precursor gas source 270 to the process volume 205. Sputter gases, reactive gases, and precursor gases may each be referred to as process gases herein. During processing, the process volume 205 can be maintained at a process pressure using a vacuum device and/or the gas flow controllers 262, 264, 271.

The substrate support 232 includes an RF bias power source 238 coupled to a bias electrode 240 disposed in the substrate support 232 via a matching network 242. The substrate support 232 includes a mechanism (not shown) that retains the substrate on the support surface 234 of the substrate support 232, such as an electrostatic chuck, a vacuum chuck, a substrate retaining clamp, or the like. The substrate support 232 includes a cooling conduit 265 disposed in the substrate support 232 where the cooling conduit 265 controllably cools the substrate support 232 and the substrate positioned thereon to a predetermined temperature, for example between about −20° C. to about 300° C. The cooling conduit 265 is coupled to a cooling fluid source 268 to provide cooling fluid (not shown). The substrate support 232 also includes a heater 267 embedded therein. The heater 267, such as a resistive element, disposed in the substrate support 232 is coupled to an optional heater power source 266 and controllably heats the substrate support 232 and the substrate positioned thereon to a predetermined temperature, for example between about −150° C. to about 500° C.

While FIG. 2 depicts one first target 204 and one second target 206, the processing chamber 200 may include one or more first targets 204 and/or one or more second targets 206. For example, 3-5 targets selected from at least one of the first targets 204 and/or the second targets 206 may be included in the processing chamber 200. Each first target 204 is operable to deposit a different material. For example, 3-5 second targets 206 may be included in the processing chamber 200. Each second target 206 is operable to deposit a different material. In one or more embodiments with the one or more first targets 204 and the one or more second target 206, each first target 204 is operable to deposit a different first material and/or each second target 206 is operable to deposit a different second material on the substrate.

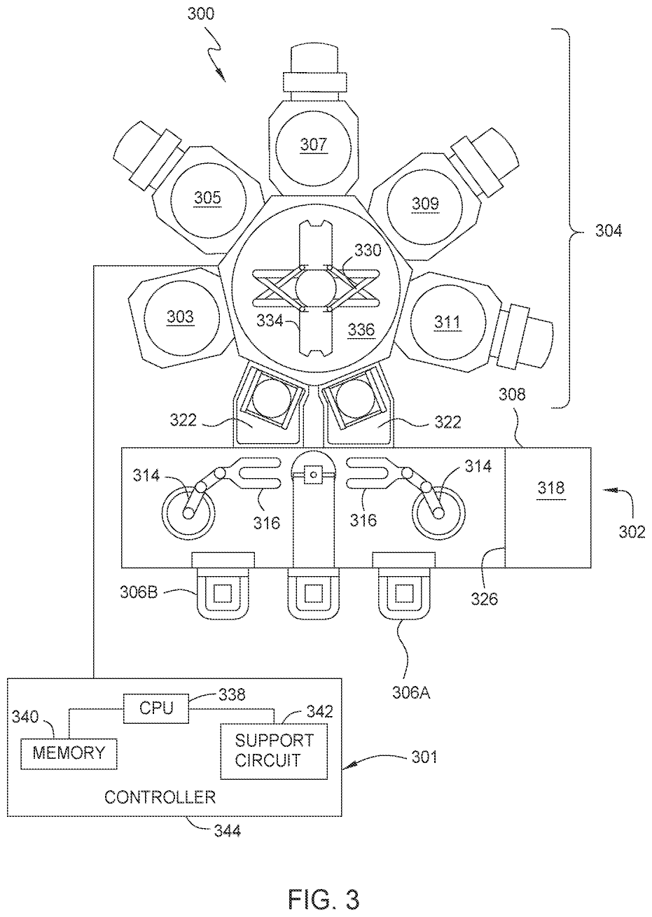

FIG. 3 is a schematic, top plan view of a cluster processing system 300, according to certain embodiments described herein. The cluster tool 300 features at least one or more of the processing chambers 100, 200 that are incorporated and integrated therein. In one embodiment, the cluster processing system 300 may be a Centura® or Endura® integrated processing system, commercially available from Applied Materials, Inc., located in Santa Clara, Calif. It is contemplated that other processing systems (including those from other manufacturers) may be adapted to benefit from the disclosure.

The cluster processing system 300 includes a vacuum-tight processing platform 304, a factory interface 302, and a system controller 344. The platform 304 includes a plurality of processing chambers 303, 305, 307, 309, 311 and at least one load-lock chamber 322 that is coupled to a vacuum substrate transfer chamber 336. Although FIG. 3 shows an embodiment of the cluster processing system 300 having five (5) processing chambers 303, 305, 307, 309, 311, in an embodiment, the processing system 300 may be configured with only two (2) processing chambers incorporating processing chambers 100 and 200 described herein. Two load lock chambers 322 are shown in FIG. 3. The factory interface 302 is coupled to the transfer chamber 336 by the load lock chambers 322.

In one embodiment, the factory interface 302 comprises at least one docking station 308 and at least one factory interface robot 314 to facilitate transfer of substrates. The docking station 308 is configured to accept one or more front opening unified pod (FOUP). Two FOUPS 306A, 306B are shown in the embodiment of FIG. 3. The factory interface robot 314 having a blade 316 disposed on one end of the robot 314 is configured to transfer the substrate from the factory interface 302 to the processing platform 304 for processing through the load lock chambers 322. Optionally, one or more metrology stations 318 may be connected to a terminal 326 of the factory interface 302 to facilitate measurement of the substrate from the FOUPS 306A-B.

Each of the load lock chambers 322 have a first port coupled to the factory interface 302 and a second port coupled to the transfer chamber 336. The load lock chambers 322 are coupled to a pressure control system (not shown) which pumps down and vents the load lock chambers 322 to facilitate passing the substrate between the vacuum environment of the transfer chamber 336 and the substantially ambient (e.g., atmospheric) environment of the factory interface 302.

The transfer chamber 336 has a vacuum robot 330 disposed therein. The vacuum robot 330 has a blade 334 capable of transferring substrates among the load lock chambers 322, a metrology system, and the processing chambers 303, 305, 307, 309, 311. In an embodiment, which can be combined with other embodiments described herein, the transfer chamber 336 prevents oxide growth or regrowth on substrates by maintaining a high vacuum, such as about 100 mT or less than about 100 mT. In another embodiment, which can be combined with other embodiments described herein, the transfer chamber 336 prevents oxide growth or regrowth on substrates by being filled with an inert gas, such as N2, Ar, and the like.

In one embodiment of the cluster processing system 300, the cluster processing system 300 may include one or more processing chambers 303, 305, 307, 309, 311, which may be a deposition chamber (e.g., physical vapor deposition chamber, chemical vapor deposition, atomic layer deposition or other deposition chambers), annealing chamber (e.g., high pressure annealing chamber, RTP chamber, laser anneal chamber), etch chamber, cleaning chamber, pre-cleaning chamber, curing chamber, lithographic exposure chamber, or other similar type of semiconductor processing chambers. In one embodiment, processing chamber 303 may be a pre-cleaning chamber, such as processing chamber 100 described herein, configured to clean the substrate prior to deposition of an optical device film. The pre-clean chamber may be configured to perform the Applied Materials SICONI™ Pre-clean process. Processing chambers 305, 307, 309 and/or 311 may be additional material deposition chambers, including processing chamber 200 described herein, or other chambers that enable interface treatment, interfacial layer deposition, and multiple-layer film stack deposition. The cluster processing system 300 may also include facets (not shown) for connecting additional chambers to the cluster processing system 300 for one or more of interface treatment, interfacial layer deposition, and multiple-layer film stack deposition.

The system controller 344 is coupled to the cluster processing system 300. The system controller 344, which may include the computing device 301 or be included within the computing device 301, controls the operation of the cluster processing system 300 using a direct control of the process chambers 303, 305, 307, 309, 311 of the cluster processing system 300. Alternatively, the system controller 344 may control the computers (or controllers) associated with the process chambers 303, 305, 307, 309, 311 and the cluster processing system 300. In operation, the system controller 344 also enables data collection and feedback from the respective chambers to optimize performance of the cluster processing system 300.

The system controller 344, much like the computing device 301 described above, generally includes a central processing unit (CPU) 338, a memory 340, and support circuits 342. The CPU 338 may be one of any form of a general purpose computer processor that can be used in an industrial setting. The support circuits 342 are conventionally coupled to the CPU 338 and may comprise cache, clock circuits, input/output subsystems, power supplies, and the like. Processes may generally be stored in the memory 340 of the system controller 344 as a software routine that, when executed by the CPU 338, causes the process chamber to perform processes of the present disclosure. The software routines transform the CPU 338 into a specific purpose computer (controller) 344. The software routines may also be stored and/or executed by a second controller (not shown) that is located remotely from the cluster processing system 300. Some or all of the method of the present disclosure may also be performed in hardware. As such, the process may be implemented in software and executed using a computer system, in hardware as, e.g., an application specific integrated circuit or other type of hardware embodiment, or as a combination of software and hardware.

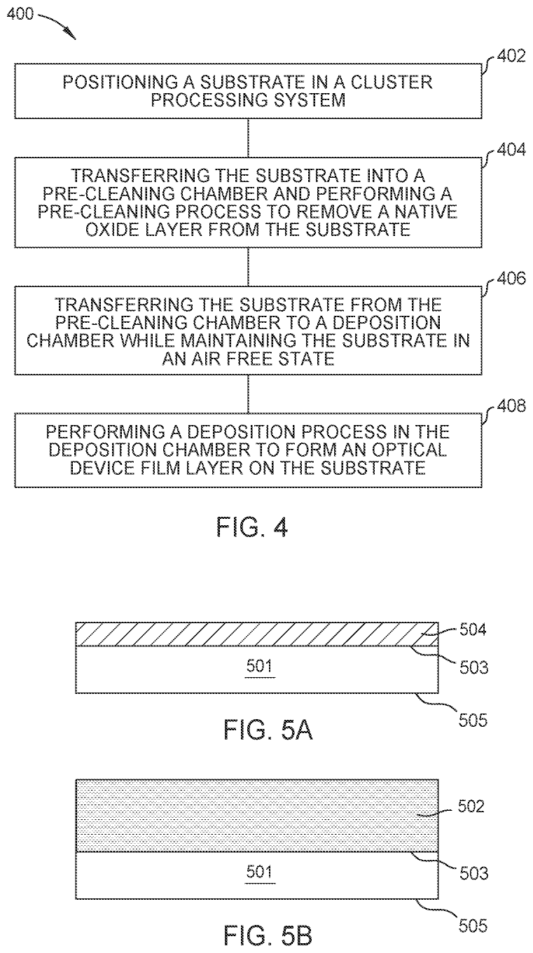

FIG. 4 is a flow diagram of an example method 400 for forming an optical device film on a substrate, according to certain embodiments described herein. FIGS. 5A and 5B are schematic cross-sectional views of a portion of a substrate 501 corresponding to various stages of the method 400.

Method 400 begins at operation 402 by positioning a substrate, such as the substrate 501 shown in FIGS. 5A, in a cluster processing system for processing. In an embodiment, the cluster processing system used to perform the method 400 described herein may be the cluster processing system 300 described in FIG. 3. In an embodiment, the substrate 501 that is to be processed may arrive to the cluster processing system 300 in a pod (not shown). The substrate 501 is transferred from the pod to one of the vacuum compatible load-lock chambers 322 by the factory interface robot 314. The substrate is then picked by the vacuum robot 330 in the transfer chamber 336 which is generally kept in a vacuum state, for transfer from one of the load-lock chambers 322 to one of the processing chambers 303, 305, 307, 309, 311 for processing.

In one embodiment, the substrate 501 is a silicon carbide (SiC) substrate. As shown in FIG. 5A, the substrate 101 includes a first surface 503 with an oxidized layer 504 disposed thereon. In embodiments described herein, the first surface 503 and a second surface 505 may both include the oxidized layer 504 disposed thereon. In embodiments of the SiC substrate, the oxidized layer 504 is a silicon oxycarbide (SiOC). The oxidized layer 504 of SiOC may have a refractive index of about 1.46 or less and the optical device substrate 501 may have a refractive index of about 2.67. The oxidized layer 504 may have a thickness of 2 nanometers (nm) or less. The difference in refractive index between the oxidized layer 504 and the optical device substrate 501 creates optical interference and leads to optical loss if an optical device film (such as an optical device film layer 502 of FIG. 5B) is deposited thereover.

At operation 404, the substrate 501 is transferred into a processing chamber, such as the pre-cleaning chamber 100 as depicted in FIG. 1, which may be incorporated into the cluster processing system 300 depicted in FIG. 3, to perform a pre-cleaning process on the substrate 501. In an embodiment, the vacuum robot 330 of the cluster processing system 300 loads the substrate 501 into the processing chamber 303 for pre-cleaning as described in operation 404.

In one embodiment, the pre-cleaning process performed at operation 404 removes a native oxide layer (such as the oxidized layer 504 of FIG. 5A) from the substrate 501. In another embodiment, the pre-cleaning process at operation 404 can remove the native oxide layer from both surfaces 503, 505 of the substrate 501.

In one embodiment, the pre-cleaning process may be performed by supplying a pre-cleaning gas mixture including hydrogen etchants. The pre-cleaning gas mixture includes at least a hydrogen containing gas. While supplying the hydrogen containing gas in the pre-cleaning gas mixture, an inert gas may also be optionally supplied during the pre-cleaning process. Suitable examples of the hydrogen containing gas include H2, NH3, H2O, H2O2, and the like. Suitable examples of the inert gas may also be supplied into the pre-cleaning gas mixture as needed. Examples of the inert gas supplied in the gas mixture include Ar, He, Ne, Kr, Xe and the like. In one particular example, the pre-cleaning gas mixture includes H2, N2, NH3, H2O, O2, NF3, CF4, Ar, and combinations thereof.

The pre-cleaning gas mixture is supplied through the chamber plasma region 121 into the substrate processing region 141 to form a remote plasma source in the chamber plasma region 121 from the pre-cleaning gas mixture for removing surface contaminants and native oxide. The amount of gases introduced into the processing chamber 100 from the pre-cleaning gas mixture may be varied and adjusted to accommodate, for example, the thickness of the native oxide or the amount of the surface contaminates to be removed.

A remote plasma power from the power source 152 is generated to form a plasma in the chamber plasma region 121 from the pre-cleaning gas mixture supplied at operation 404. The plasma generated remotely in the chamber plasma region 121 during the pre-cleaning process at operation 404 may have the etchants dissociated to form a relatively mild and gentle etchants, so as to slowly, gently and gradually etch the surface contaminants and native oxide, e.g., an isotropic etching process. The remote plasma process provides good control for the interface cleaning and promotes high etching selectivity.

In an embodiment, which can be combined with other embodiments herein, the support assembly 180 of the pre-cleaning chamber 100 is operable to heat the substrate 501 to between about 400 degrees Celsius and about 1500 degrees Celsius during the pre-cleaning process.

In another embodiment, which can be combined with other embodiments herein, the pre-cleaning chamber 100 maintains a pressure of about 100 mT to atmospheric pressure in the processing region 141 during the pre-cleaning process.

At operation 406, the substrate 501 is transferred from the pre-cleaning chamber 100 to a deposition chamber while maintaining the substrate 501 in an air free state. In an embodiment, which can be combined with other embodiments described herein, the substrate 501 is maintained in a high vacuum environment, such as about 100 mT or less, during transfer to prevent oxide growth on the substrate 501. In another embodiment, which can be combined with other embodiments described herein, the substrate 501 is maintained in a space filled with an inert gas, such as N2, Ar, and the like, during transfer to prevent oxide growth on the substrate 501.

In an embodiment, when the pre-cleaning chamber 100 is incorporated into the cluster processing system 300 depicted in FIG. 3, the substrate 501 in the pre-cleaning chamber 100 is picked by the vacuum robot 330 in operation 406 for transfer to a deposition chamber in the cluster processing system 300. The vacuum robot 330 in the transfer chamber 336 is kept in a vacuum state to facilitate passing the substrate 501 in an air free environment between the pre-cleaning chamber 100 and one of the processing chambers 303, 305, 307, 309, 311 configured for performing a deposition process.

At operation 408, a deposition process is performed to form an optical device film layer 502 on the substrate 501, as shown in FIG. 5B. The deposition process may be a PVD process performed at the PVD processing chamber 200 depicted in FIG. 2, which may be incorporated into the cluster processing system 300 depicted in FIG. 3, to perform the deposition process on the substrate 501. Alternatively, other deposition process techniques may be performed, such as chemical vapor deposition (CVD), plasma enhanced chemical vapor deposition (PECVD), atomic layer deposition (ALD), plasma enhanced atomic layer deposition (PEALD), low pressure chemical vapor deposition (LPCVD), etc. in a corresponding deposition chamber.

The optical device film layer 502 deposited on the substrate 501 in operation 408 includes, but is not limited to, materials containing germanium, silicon, titanium oxide, niobium oxide, silicon nitride, hafnium oxide, tantalum oxide, scandium oxide, or combinations thereof. In one embodiment, the optical device film 102 may be disposed over the first surface 503 and the second surface 505 of the substrate 501 opposite of the first surface 503.

In summation, using aspects described herein, it has been found that by removing native oxides having a low refractive index from a substrate, such as a SiC substrate, to form an oxide free surface and maintaining such oxide free surface in an air free state prior to depositing an optical device film on the substrate, optical interference and loss usually caused by interfacial oxide layers, such as by an SiOC interfacial layer between an optical device film layer and a SiC substrate, can be minimized and/or removed altogether. In certain embodiments, a system and method is provided to remove native oxides layer from a substrate and form an optical device film on the substrate all while maintaining the substrate in an air free state. In one embodiment, the method includes positioning the substrate in a pre-cleaning chamber incorporated into a cluster processing system to remove native oxides from the substrate and transferring the substrate to a deposition chamber also incorporated into the cluster processing system to deposit an optical device film, all while maintaining the substrate in an air free environment to prevent oxide growth on the substrate.

While the foregoing is directed to examples of the present disclosure, other and further examples of the disclosure may be devised without departing from the basic scope thereof, and the scope thereof is determined by the claims that follow.

What is claimed is:

1. A method for forming an optical device film, comprising:
pre-cleaning a substrate in a pre-cleaning chamber disposed in a cluster processing system to remove a native oxide layer from a top surface of the substrate;
transferring the substrate to a deposition chamber disposed in the cluster processing system while maintaining the substrate in an air free state; and
forming an optical device film layer on the top surface of the substrate in the deposition chamber disposed in the cluster processing system.

2. The method of claim 1, wherein the substrate comprises a silicon carbide (SiC) substrate.

3. The method of claim 1, wherein the native oxide layer comprises a silicon oxycarbide (SiOC) layer.

4. The method of claim 2, wherein pre-cleaning the silicon carbide substrate further comprises heating and maintaining the silicon carbide substrate temperature between about 400 degrees Celsius and about 1500 degrees Celsius.

5. The method of claim 1, wherein pre-cleaning the substrate further comprises maintaining a pressure of about 100 mT to atmospheric pressure in the pre-cleaning chamber disposed in the cluster processing system.

6. The method of claim 1, wherein pre-cleaning the substrate further comprises removing a second native oxide layer from a bottom surface of the substrate.

7. The method of claim 1, wherein maintaining the substrate in an air free state comprises maintaining the substrate in an high vacuum environment at a pressure of about 100 mT or less.

8. The method of claim 1, wherein maintaining the substrate in the air free state comprises flowing an inert gas when transferring the substrate between the pre-cleaning chamber and the deposition chamber.

9. The method of claim 1, wherein maintaining the substrate in the air free state when transferring the substrate between the pre-cleaning chamber and the deposition chamber prevents oxide growth on the top surface of the substrate.

10. A method for forming an optical device film, comprising:
positioning a SiC substrate in a pre-cleaning chamber of a cluster processing system;
pre-cleaning the SiC substrate in the pre-cleaning chamber disposed in a cluster processing system to remove a native SiOC layer from one or more surfaces of the SiC substrate;
transferring the SiC substrate to a deposition chamber disposed in the cluster processing system while maintaining the SiC substrate in an air free state to prevent oxide growth on the one or more surfaces of the SiC substrate; and
forming an optical device film layer on the one or more surfaces of the SiC substrate in the deposition chamber disposed in the cluster processing system.

11. The method of claim 10, wherein pre-cleaning the SiC substrate further comprises heating and maintaining the SiC substrate temperature between about 400 degrees Celsius and about 1500 degrees Celsius.

12. The method of claim 10, wherein maintaining the SiC substrate in an air free state comprises maintaining the SiC substrate in an high vacuum environment at a pressure of about 100 mT or less.

13. The method of claim 10, wherein maintaining the SiC substrate in an air free state comprises flowing an inert gas when transferring the substrate between the pre-cleaning chamber and the deposition chamber.

14. A cluster processing system, comprising:
a pre-cleaning chamber configured to remove a native oxide layer;
a deposition chamber configured to form an optical device film layer; and
a transfer chamber configured to maintain an air free environment when transitioning between the pre-cleaning chamber and the first deposition chamber.

15. The cluster processing system of claim 14, further comprising a computer readable media, when executed by a controller of the cluster processing system, causes the cluster processing system to:
pre-clean a substrate in a pre-cleaning chamber disposed in the cluster processing system to remove the native oxide layer from one or more surfaces of the substrate;
transfer the substrate to a deposition chamber disposed in the cluster processing system while maintaining the substrate in an air free state; and
form an optical device film layer on the substrate in the deposition chamber disposed in the cluster processing system.

16. The cluster processing system of claim 15, wherein the substrate comprises a silicon carbide substrate and the native oxide layer comprises a silicon oxycarbide layer.

17. The cluster processing system of claim 16, wherein the pre-cleaning chamber is configured to heat and maintain the silicon carbide substrate temperature between about 400 degrees Celsius and about 1500 degrees Celsius.

18. The cluster processing system of claim 15, wherein the pre-cleaning chamber is configured to maintain the substrate in a pressure of about 100 mT to atmospheric pressure.

19. The cluster processing system of claim 15, wherein the transfer chamber is configured to maintain the substrate in an high vacuum environment at a pressure of about 100 mT or less.

20. The cluster processing system of claim 14, wherein the transfer chamber is configured to flow an inert gas to maintain an air free environment when transitioning between the pre-cleaning chamber and the first deposition chamber in the cluster processing system.
